(19) United States
(12) Patent Application Publication
(10) Pub. No.: US 2025/0234494 A1
(43) Pub. Date: Jul. 17, 2025

(54) ELECTRONIC DEVICE COMPRISING HEAT DISSIPATION STRUCTURE

(71) Applicant: Samsung Electronics Co., Ltd., Suwon-si (KR)

(72) Inventor: Minuk KIM, Suwon-si (KR)

(21) Appl. No.: 19/097,550

(22) Filed: Apr. 1, 2025

Related U.S. Application Data
(63) Continuation of application No. PCT/KR2023/015132, filed on Sep. 27, 2023.

(30) Foreign Application Priority Data
Oct. 11, 2022 (KR) 10-2022-0129523
Nov. 11, 2022 (KR) 10-2022-0150510

(51) Int. Cl. H05K 7/20; G06F 1/16; G06F 1/20

(52) U.S. Cl. CPC H05K 7/20445; G06F 1/1656; G06F 1/203; H05K 7/209

(57) ABSTRACT

An example electronic device may include a heat generating element including an electronic component in which heat is generated during the operation of the electronic device; and a heat dissipation structure configured to support the heat generating element, wherein the heat dissipation structure includes a first frame including a first metal, and a second frame, at least a portion of which is disposed inside the first frame, at least a portion of which is exposed to the outside through one surface of the first frame, and which includes a second metal, and the second frame includes a heat transfer part that is in contact with the heat generating element and a heat dissipation part that is disposed at a distance from the heat generating element, and may extend from the heat transfer part to the heat dissipation part.

### CROSS-REFERENCE TO RELATED APPLICATIONS

This application is a continuation o International Application No. PCT/KR2023/015132, designating the United States, filed on Sep. 27, 2023, in the Korean Intellectual Property Receiving Office and claiming priority to Korean Patent Application Nos. 10-2022-0129523, filed on Oct. 11, 2022, and 10-2022-0150510, filed on Nov. 11, 2022, in the Korean Intellectual Property Office, the disclosures of each of which are incorporated by reference herein in their entireties.

### BACKGROUND

### Field

The present disclosure relates to an electronic device including a heat dissipation structure.

### Description of Related Art

A mechanism (e.g., bracket) in contact with heat-generating components (e.g., printed circuit board, processor, battery) inside a portable electronic device may be manufactured through a die casting method using a single material of metal. For example, the mechanism in contact with the heat-generating components may be made of non-ferrous metals such as aluminum, magnesium, or zinc. Aluminum, magnesium, or zinc can be applied using the die casting method and are easy to process, making them suitable for use as mechanisms in portable electronic devices.

### SUMMARY

Due to the increased performance and integration of portable electronic devices, the heat generated by the electronic components inside an electronic device may increase. In order to reduce the heat transmitted to a user of the portable electronic device, it is necessary to quickly dissipate the heat generated by the electronic components to the surrounding environment. A mechanism made of a single material of metal may have limitations in quickly dissipating the heat generated by the electronic components to the surrounding environment.

To improve the thermal conductivity of the mechanism, graphite sheets, copper sheets, or the like may be attached. However, when applying such methods, the rigidity of the mechanism may decrease or the thickness of the electronic device may increase. When the mechanism is made solely of copper or copper alloys to improve thermal conductivity of the mechanism, the weight and manufacturing cost of the electronic device may increase.

An electronic device according to an example embodiment of the present disclosure may include a heat generating element (heat source) that includes an electronic component in which heat is generated during the operation of the electronic device, and a heat dissipation structure that supports the heat generating element.

In an embodiment, the heat dissipation structure may include a first frame that includes a first metal, and a second frame that includes a second metal, where at least a portion of the second frame is disposed inside the first frame and at least a portion of the second frame is exposed to the outside through one surface of the first frame.

In an example embodiment, the second frame may include a heat transfer part that is in contact with the heat generating element and a heat dissipation part that is disposed at a distance from the heat generating element.

In an example embodiment, the second frame may extend from the heat transfer part to the heat dissipation part.

An electronic device including a heat dissipation structure according to example embodiments of the present disclosure can quickly dissipate heat generated by the electronic components without increasing a thickness of the electronic device or reducing its mechanical strength.

An electronic device including the heat dissipation structure according to example embodiments of the present disclosure may include a material with improved mechanical strength compared to a material used for die casting.

### BRIEF DESCRIPTION OF THE DRAWINGS

The above and other aspects, features and advantages of certain embodiments of the present disclosure will be more apparent from the following detailed description, taken in conjunction with the accompanying drawings, in which:

FIG. 1 is a block diagram of an example electronic device in a network environment according to various embodiments;

FIG. 2 is a conceptual view of an example electronic device according to various embodiments;

FIG. 3 is an exploded perspective view of an example electronic device according to various embodiments;

FIG. 4A, FIG. 4B, and FIG. 4C are views illustrating an example electronic device according to example embodiments;

FIG. 5A, FIG. 5B, FIG. 5C, and FIG. 5D are views illustrating an example first frame and an example second frame according to various embodiments; and

FIG. 6A, FIG. 6B, and FIG. 6C are views illustrating an example second frame according to various embodiments.

### DETAILED DESCRIPTION

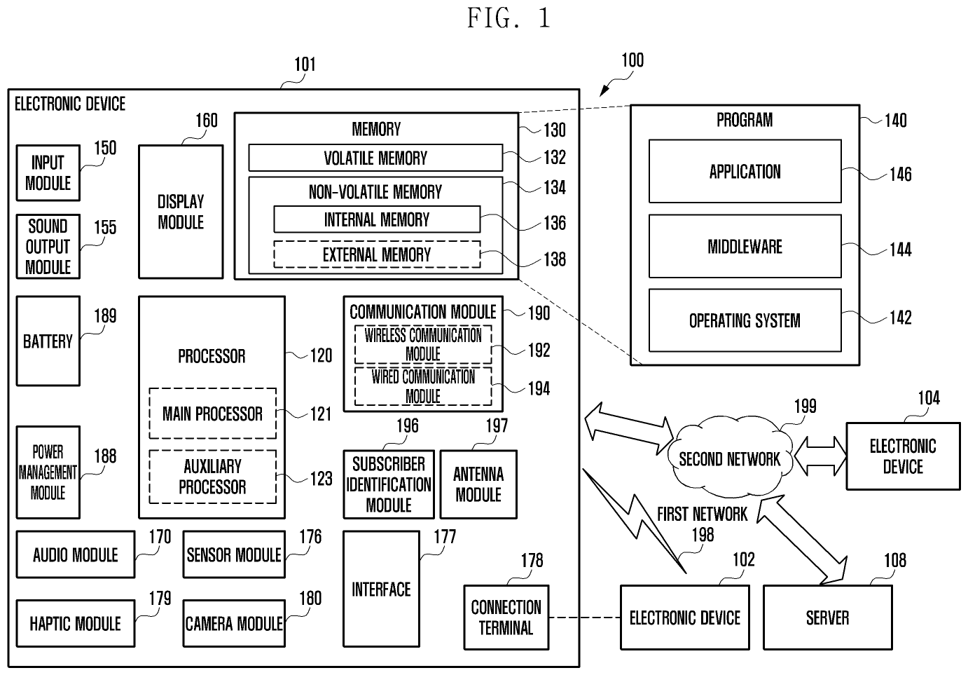

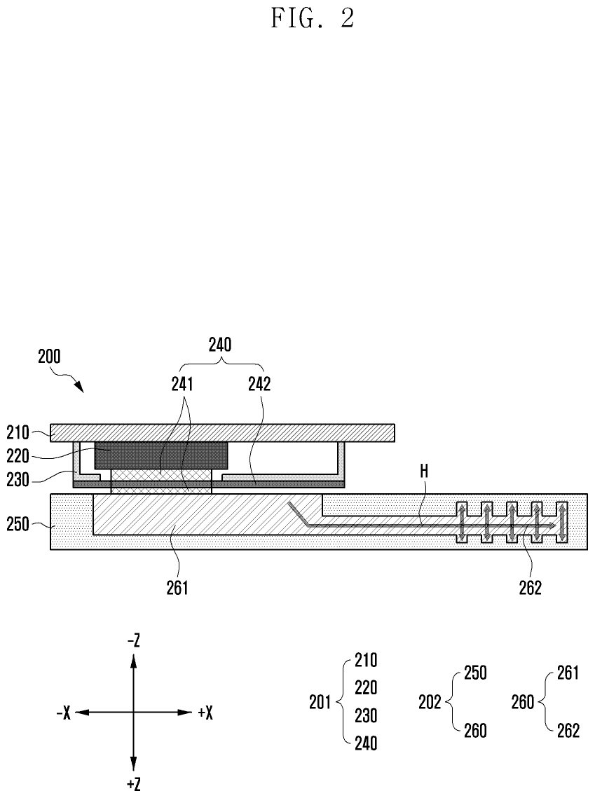

FIG. 1 is a block diagram illustrating an example electronic device 101 in a network environment 100 according to various embodiments. Referring to FIG. 1, the electronic device 101 in the network environment 100 may communicate with an electronic device 102 via a first network 198 (e.g., a short-range wireless communication network), or at least one of an electronic device 104 or a server 108 via a second network 199 (e.g., a long-range wireless communication network). According to an embodiment, the electronic device 101 may communicate with the electronic device 104 via the server 108. According to an embodiment, the electronic device 101 may include a processor 120, memory 130, an input module 150, a sound output module 155, a display module 160, an audio module 170, a sensor module 176, an interface 177, a connecting terminal 178, a haptic module 179, a camera module 180, a power management module 188, a battery 189, a communication module 190, a subscriber identification module (SIM) 196, or an antenna module 197. In various embodiments, at least one of the components (e.g., the connecting terminal 178) may be omitted from the electronic device 101, or one or more other components may be added in the electronic device 101. In various embodiments, some of the components (e.g., the sensor module 176, the camera module 180, or the antenna module 197) may be implemented as a single component (e.g., the display module 160).

The processor 120 (including, e.g., processing circuitry) may execute, for example, software (e.g., a program 140) to control at least one other component (e.g., a hardware or software component) of the electronic device 101 coupled with the processor 120, and may perform various data processing or computation. According to an embodiment, as at least part of the data processing or computation, the processor 120 may store a command or data received from another component (e.g., the sensor module 176 or the communication module 190) in volatile memory 132, process the command or the data stored in the volatile memory 132, and store resulting data in non-volatile memory 134. According to an embodiment, the processor 120 may include a main processor 121 (e.g., a central processing unit (CPU) or an application processor (AP)), or an auxiliary processor 123 (e.g., a graphics processing unit (GPU), a neural processing unit (NPU), an image signal processor (ISP), a sensor hub processor, or a communication processor (CP)) that is operable independently from, or in conjunction with, the main processor 121. For example, when the electronic device 101 includes the main processor 121 and the auxiliary processor 123, the auxiliary processor 123 may be adapted to consume less power than the main processor 121, or to be specific to a specified function. The auxiliary processor 123 may be implemented as separate from, or as part of, the main processor 121.

The auxiliary processor 123 may control at least some of functions or states related to at least one component (e.g., the display module 160, the sensor module 176, or the communication module 190) among the components of the electronic device 101, instead of the main processor 121 while the main processor 121 is in an inactive (e.g., sleep) state, or together with the main processor 121 while the main processor 121 is in an active state (e.g., executing an application). According to an embodiment, the auxiliary processor 123 (e.g., an image signal processor or a communication processor) may be implemented as part of another component (e.g., the camera module 180 or the communication module 190) functionally related to the auxiliary processor 123. According to an embodiment, the auxiliary processor 123 (e.g., the neural processing unit) may include a hardware structure specified for artificial intelligence model processing. An artificial intelligence model may be generated by machine learning. Such learning may be performed, e.g., by the electronic device 101 where the artificial intelligence is performed or via a separate server (e.g., the server 108). Learning algorithms may include, but are not limited to, e.g., supervised learning, unsupervised learning, semi-supervised learning, or reinforcement learning. The artificial intelligence model may include a plurality of artificial neural network layers. The artificial neural network may be a deep neural network (DNN), a convolutional neural network (CNN), a recurrent neural network (RNN), a restricted Boltzmann machine (RBM), a deep belief network (DBN), a bidirectional recurrent deep neural network (BRDNN), deep Q-network or a combination of two or more thereof but is not limited thereto. The artificial intelligence model may, additionally or alternatively, include a software structure other than the hardware structure.

The memory 130 may store various data used by at least one component (e.g., the processor 120 or the sensor module 176) of the electronic device 101. The various data may include, for example, software (e.g., the program 140) and input data or output data for a command related thereto. The memory 130 may include the volatile memory 132 or the non-volatile memory 134.

The program 140 may be stored in the memory 130 as software, and may include, for example, an operating system (OS) 142, middleware 144, or an application 146.

The input module 150 (including, e.g., input circuitry) may receive a command or data to be used by another component (e.g., the processor 120) of the electronic device 101, from the outside (e.g., a user) of the electronic device 101. The input module 150 may include, for example, a microphone, a mouse, a keyboard, a key (e.g., a button), or a digital pen (e.g., a stylus pen).

The sound output module 155 (including, e.g., sound output circuitry) may output sound signals to the outside of the electronic device 101. The sound output module 155 may include, for example, a speaker or a receiver. The speaker may be used for general purposes, such as playing multimedia or playing record. The receiver may be used for receiving incoming calls. According to an embodiment, the receiver may be implemented as separate from, or as part of, the speaker.

The display module 160 may visually provide information to the outside (e.g., a user) of the electronic device 101. The display module 160 may include, for example, a display, a hologram device, or a projector and control circuitry to control a corresponding one of the display, hologram device, and projector. According to an embodiment, the display module 160 may include a touch sensor adapted to detect a touch, or a pressure sensor adapted to measure the intensity of force incurred by the touch.

The audio module 170 (including, e.g., audio circuitry) may convert a sound into an electrical signal and vice versa. According to an embodiment, the audio module 170 may obtain the sound via the input module 150, or output the sound via the sound output module 155 or a headphone of an external electronic device (e.g., an electronic device 102) directly (e.g., wiredly) or wirelessly coupled with the electronic device 101.

The sensor module 176 may detect an operational state (e.g., power or temperature) of the electronic device 101 or an environmental state (e.g., a state of a user) external to the electronic device 101, and then generate an electrical signal or data value corresponding to the detected state. According to an embodiment, the sensor module 176 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 177 (including, e.g., interface circuitry) may support one or more specified protocols to be used for the electronic device 101 to be coupled with the external electronic device (e.g., the electronic device 102) directly (e.g., wiredly) or wirelessly. According to an embodiment, the interface 177 may include, for example, a high definition multimedia interface (HDMI), a universal serial bus (USB) interface, a secure digital (SD) card interface, or an audio interface.

A connecting terminal 178 may include a connector via which the electronic device 101 may be physically connected with the external electronic device (e.g., the electronic device 102). According to an embodiment, the connecting terminal 178 may include, for example, a HDMI connector, a USB connector, a SD card connector, or an audio connector (e.g., a headphone connector).

The haptic module 179 may convert an electrical signal into a mechanical stimulus (e.g., a vibration or a movement) or electrical stimulus which may be recognized by a user via tactile sensation or kinesthetic sensation. According to an embodiment, the haptic module 179 may include, for example, a motor, a piezoelectric element, or an electric stimulator.

The camera module 180 (including, e.g., a camera) may capture a still image or moving images. According to an embodiment, the camera module 180 may include one or more lenses, image sensors, image signal processors, or flashes.

The power management module 188 may manage power supplied to the electronic device 101. According to an embodiment, the power management module 188 may be implemented as at least part of, for example, a power management integrated circuit (PMIC).

The battery 189 may supply power to at least one component of the electronic device 101. According to an embodiment, the battery 189 may include, for example, a primary cell which is not rechargeable, a secondary cell which is rechargeable, or a fuel cell.

The communication module 190 (including, e.g., communication circuitry) may support establishing a direct (e.g., wired) communication channel or a wireless communication channel between the electronic device 101 and the external electronic device (e.g., the electronic device 102, the electronic device 104, or the server 108) and performing communication via the established communication channel. The communication module 190 may include one or more communication processors that are operable independently from the processor 120 (e.g., the application processor (AP)) and supports a direct (e.g., wired) communication or a wireless communication. According to an embodiment, the communication module 190 may include a wireless communication module 192 (including, e.g., wireless communication circuitry) (e.g., a cellular communication module, a short-range wireless communication module, or a global navigation satellite system (GNSS) communication module) or a wired communication module 194 (including, e.g., wired communication circuitry) (e.g., a local area network (LAN) communication module or a power line communication (PLC) module). A corresponding one of these communication modules may communicate with the external electronic device via the first network 198 (e.g., a short-range communication network, such as Bluetooth™, wireless-fidelity (Wi-Fi) direct, or infrared data association (IrDA)) or the second network 199 (e.g., a long-range communication network, such as a legacy cellular network, a 5G network, a next-generation communication network, the Internet, or a computer network (e.g., LAN or wide area network (WAN)). These various types of communication modules may be implemented as a single component (e.g., a single chip), or may be implemented as multi components (e.g., multi chips) separate from each other. The wireless communication module 192 may identify and authenticate the electronic device 101 in a communication network, such as the first network 198 or the second network 199, using subscriber information (e.g., international mobile subscriber identity (IMSI)) stored in the subscriber identification module 196.

The wireless communication module 192 may support a 5G network, after a 4G network, and next-generation communication technology, e.g., new radio (NR) access technology. The NR access technology may support enhanced mobile broadband (eMBB), massive machine type communications (mMTC), or ultra-reliable and low-latency communications (URLLC). The wireless communication module 192 may support a high-frequency band (e.g., the mmWave band) to achieve, e.g., a high data transmission rate. The wireless communication module 192 may support various technologies for securing performance on a high-frequency band, such as, e.g., beamforming, massive multiple-input and multiple-output (massive MIMO), full dimensional MIMO (FD-MIMO), array antenna, analog beam-forming, or large scale antenna. The wireless communication module 192 may support various requirements specified in the electronic device 101, an external electronic device (e.g., the electronic device 104), or a network system (e.g., the second network 199). According to an embodiment, the wireless communication module 192 may support a peak data rate (e.g., 20 Gbps or more) for implementing eMBB, loss coverage (e.g., 164 dB or less) for implementing mMTC, or U-plane latency (e.g., 0.5 ms or less for each of downlink (DL) and uplink (UL), or a round trip of 1 ms or less) for implementing URLLC.

The antenna module 197 may transmit or receive a signal or power to or from the outside (e.g., the external electronic device) of the electronic device 101. According to an embodiment, the antenna module 197 may include an antenna including a radiating element including a conductive material or a conductive pattern formed in or on a substrate (e.g., a printed circuit board (PCB)). According to an embodiment, the antenna module 197 may include a plurality of antennas (e.g., array antennas). In such a case, at least one antenna appropriate for a communication scheme used in the communication network, such as the first network 198 or the second network 199, may be selected, for example, by the communication module 190 (e.g., the wireless communication module 192) from the plurality of antennas. The signal or the power may then be transmitted or received between the communication module 190 and the external electronic device via the selected at least one antenna. According to an embodiment, another component (e.g., a radio frequency integrated circuit (RFIC)) other than the radiating element may be additionally formed as part of the antenna module 197.

According to various embodiments, the antenna module 197 may form a mmWave antenna module. According to an embodiment, the mmWave antenna module may include a printed circuit board, a RFIC disposed on a first surface (e.g., the bottom surface) of the printed circuit board, or adjacent to the first surface and capable of supporting a designated high-frequency band (e.g., the mmWave band), and a plurality of antennas (e.g., array antennas) disposed on a second surface (e.g., the top or a side surface) of the printed circuit board, or adjacent to the second surface and capable of transmitting or receiving signals of the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, commands or data may be transmitted or received between the electronic device 101 and the external electronic device 104 via the server 108 coupled with the second network 199. Each of the electronic devices 102 or 104 may be a device of a same type as, or a different type, from the electronic device 101. According to an embodiment, all or some of operations to be executed at the electronic device 101 may be executed at one or more of the external electronic devices 102, 104, or 108. For example, if the electronic device 101 should perform a function or a service automatically, or in response to a request from a user or another device, the electronic device 101, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 101. The electronic device 101 may provide the outcome, with or without further processing of the outcome, as at least part of a reply to the request. To that end, a cloud computing, distributed computing, mobile edge computing (MEC), or client-server computing technology may be used, for example. The electronic device 101 may provide ultra low-latency services using, e.g., distributed computing or mobile edge computing. In an embodiment, the external electronic device 104 may include an internet-of-things (IoT) device. The server 108 may be an intelligent server using machine learning and/or a neural network. According to an embodiment, the external electronic device 104 or the server 108 may be included in the second network 199. The electronic device 101 may be applied to intelligent services (e.g., smart home, smart city, smart car, or healthcare) based on 5G communication technology or IoT-related technology.

FIG. 2 is a conceptual view of an example electronic device 200 according to various embodiments of the present disclosure.

In describing the electronic device 200 according to an embodiment of the present disclosure, the width direction of the electronic device 200 may refer, for example, to the x-axis direction, and the height direction of the electronic device 200 may refer, for example, to the z-axis direction.

The electronic device 200 according to an embodiment of the present disclosure may include a heat generating element 201 and/or a heat dissipation structure 202. The heat generating element 201 (heat source) may refer, for example, to an area inside the electronic device 200 where heat is generated. The heat dissipation structure 202 may refer, for example, to an area where the heat generating element 201 is disposed and supported. The heat dissipation structure 202 may serve to receive and dissipate the heat generated by the heat generating element 201.

In an embodiment, the heat generating element 201 may include a printed circuit board 210, an electronic component 220, a shield can 230, and/or a heat transfer member 240.

In an embodiment, the electronic component 220 may be disposed on the printed circuit board 210. For example, the electronic component 220 may be disposed on a surface of the printed circuit board 210 facing the direction of the heat dissipation structure 202 (e.g., positive z-axis direction).

In an embodiment, the electronic component 220 may be a component that generates heat during the operation of the electronic device 200. For example, the electronic component 220 may refer to a processor (e.g., processor 120 in FIG. 1) and/or a memory (e.g., memory 130 in FIG. 1). The processor included in the electronic component 220 (e.g., processor 120 in FIG. 1) may be an application processor.

In an embodiment, the shield can 230 may be disposed to surround the outer periphery of the electronic component 220. The shield can 230 may serve to shield noise generated by the electronic component 220. The noise from the electronic component 220 may cause electromagnetic interference (EMI) that degrades the radio frequency (RF) signal performance of the electronic device 200. The shield can 230 may shield the noise generated from the electronic component 220 to reduce electromagnetic interference caused by the noise.

In an embodiment, the heat generated by the electronic component 220 may be transferred to the heat dissipation structure 202 through the heat transfer member 240. For example, the heat generated by the electronic component 220 may be transferred to a second frame 260 of the heat dissipation structure 202 through the heat transfer member 240.

In an embodiment, the heat transfer member 240 may include a first heat transfer member 241 and/or a second heat transfer member 242. The first heat transfer member 241 and the second heat transfer member 242 may include solid materials and/or liquid materials. For example, the first heat transfer member 241 may include silicone TIM (silicone thermal interface material). The second heat transfer member may include nano TIM (nano thermal interface material).

In an embodiment, two first heat transfer members 241 may be disposed with the second heat transfer member 242 interposed therebetween. For example, one of the first heat transfer members 241 may be disposed on the surface of the second heat transfer member 242 facing the negative z-axis direction, and the other first heat transfer member 241 may be disposed on the surface of the second heat transfer member 242 facing the positive z-axis direction.

With reference to FIG. 2, although the electronic component 220 of the heat generating element 201 is illustrated as not being in direct contact with the heat dissipation structure 202, and the heat transfer member 240 of the heat generating element 201 is in contact with the heat dissipation structure 202, this is illustrative, and the form of contact between the heat generating element 201 and the heat dissipation structure 202 is not limited thereto. For example, the electronic component 220 of the heat generating element 201 and the heat dissipation structure 202 may be in direct contact, allowing the heat from the electronic component 220 to be transferred to the heat dissipation structure 202.

In an embodiment, the heat dissipation structure 202 of the electronic device 200 may include a first frame 250 and/or the second frame 260.

In an embodiment, the first frame 250 may form the outer shape of the heat dissipation structure 202. The first frame 250 may extend along the width direction (e.g., the x-axis direction), height direction (e.g., the z-axis direction), and length direction (e.g., a direction perpendicular to both the x-axis and z-axis) of the electronic device 200.

In an embodiment, the second frame 260 may be disposed inside the first frame 250. For example, the first frame 250 may be disposed to surround at least a portion of the second frame 260.

In an embodiment, the second frame 260 may include a heat transfer part 261 and/or a heat dissipation part 262. The heat transfer part 261 may be an area that is in direct contact with the heat generating element 201 and receives the heat generated by the heat generating element 201.

In an embodiment, at least a portion of the second frame 260 may be exposed to the outside of the first frame 250. At least a portion of the heat transfer part 261 of the second frame 260 may be exposed to the outside of the first frame 250 and in contact with the heat generating element 201. For example, the heat transfer part 261 may be in contact with the heat transfer member 240 of the heat generating element 201 on the surface facing the direction toward the electronic component 220 (e.g., the negative z-axis direction).

In an embodiment, the heat dissipation part 262 may be an area that dissipates the transferred heat. The heat dissipation part 262 may be positioned at a distance from the heat generating element 201 and the heat transfer part 261. For example, with reference to FIG. 2, the heat dissipation part 262 may be positioned at a predetermined distance in the width direction of the electronic device 200 (e.g., the x-axis direction) with respect to the heat generating element 201 and the heat transfer part 261.

In an embodiment, the heat generated by the electronic component 220 may be transferred to the heat dissipation part 262 through the heat transfer part 261. For example, the heat generated by the electronic component 220 may diffuse along a heat transfer path H illustrated in FIG. 2 and be transferred to the heat dissipation part 262. The heat transfer path H may extend from the heat transfer part 261 toward the heat dissipation part 262, following the width direction of the electronic device 200 (e.g., the x-axis direction).

In an embodiment, the first frame 250 may include a first metal, and the second frame 260 may include a second metal. The first metal may include aluminum, magnesium, and/or zinc, to which the die casting method is applicable. The second metal may include a metal with a higher thermal conductivity than the first metal. For example, the second frame 260 may include copper and/or copper alloys.

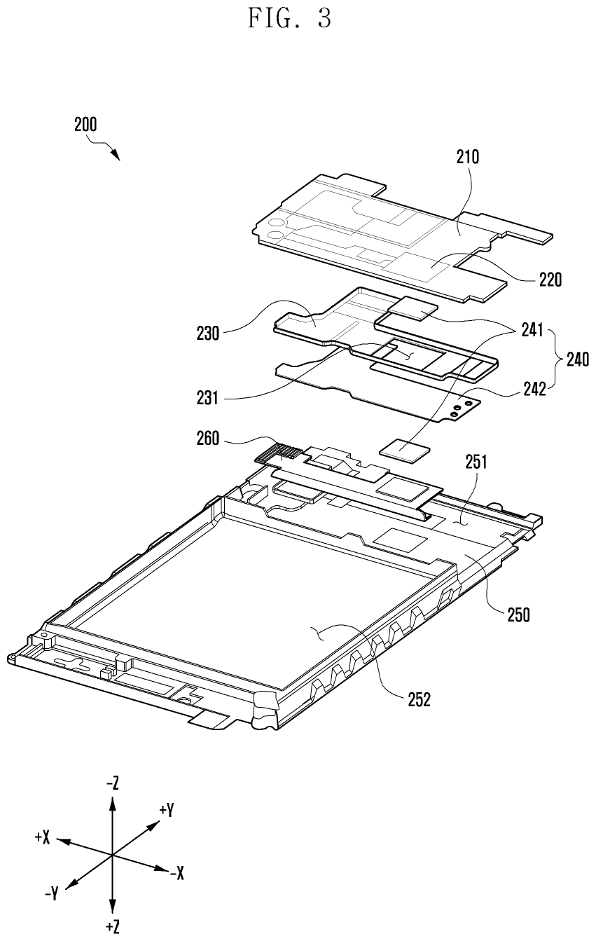

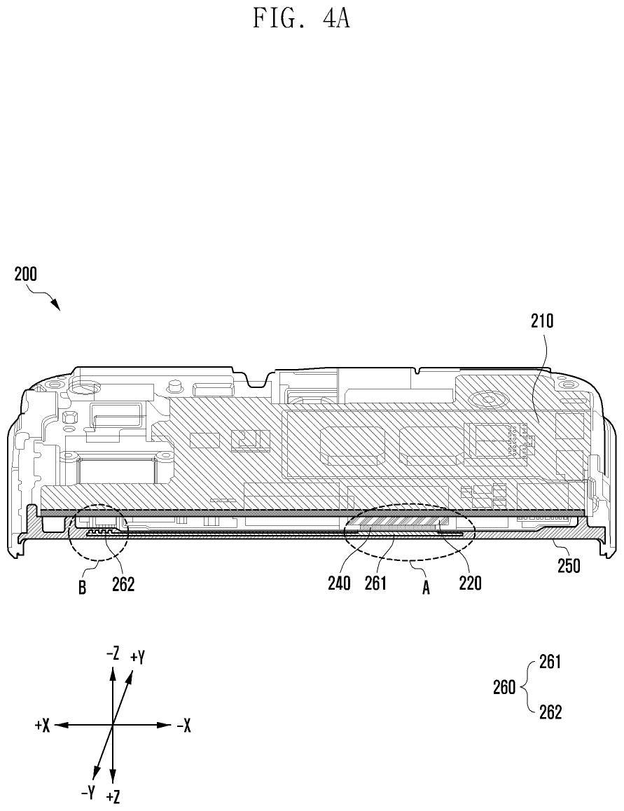

FIG. 3 is an exploded perspective view of an example electronic device 200 according to various embodiments of the present disclosure.

With reference to FIG. 3, the electronic device 200 according to an embodiment of the present disclosure may include the printed circuit board 210, the electronic component 220, the shield can 230, the heat transfer member 240, the first frame 250, and/or the second frame 260.

In an embodiment, the electronic component 220 may be disposed in one direction of the printed circuit board 210. For example, with respect to the printed circuit board 210, the electronic component 220 may be disposed in a direction toward the first frame 250 and second frame 260 (e.g., the positive z-axis direction).

In FIG. 2 and FIG. 3, the electronic component 220 is illustrated as a single component disposed on the printed circuit board 210, but this is illustrative, and the number of electronic components 220 disposed on the printed circuit board 210 is not limited thereto. For example, multiple electronic components 220 may be disposed on the printed circuit board 210.

In an embodiment, the shield can 230 may be disposed to surround the outer periphery of the electronic component 220. The shield can 230 may serve to shield noise generated by the electronic component 220.

In an embodiment, the shield can 230 may include a shield can opening 231 in at least a portion thereof. The shield can opening 231 may be formed at a position that overlaps the electronic component 220. For example, the position where the shield can opening 231 is formed may be substantially the same as the position where the electronic component 220 is disposed, based on the width direction (e.g., the x-axis direction) and length direction (e.g., the y-axis direction) of the electronic device 200.

In an embodiment, the heat transfer member 240 may include the first heat transfer member 241 and/or the second heat transfer member 242.

In an embodiment, the first heat transfer member 241 may be disposed on one surface of the electronic component 220. For example, with respect to the electronic component 220, the first heat transfer member 241 may be disposed on the surface facing the direction toward the first frame 250 and second frame 260 (e.g., the positive z-axis direction).

In an embodiment, the first heat transfer member 241 may be disposed at a position that overlaps the position where the shield can opening 231 is formed. The first heat transfer member 241 may be formed smaller compared to the length of the shield can opening 231, which extends in the width direction (e.g., the x-axis direction) and length direction (e.g., the y-axis direction) of the electronic device 200.

In an embodiment, the second heat transfer member 242 may be disposed in one direction of the shield can 230. For example, with respect to the shield can 230, the second heat transfer member 242 may be disposed in the opposite direction of the direction in which the printed circuit board 210 is positioned (e.g., the positive z-axis direction). The second heat transfer member 242 may be disposed in contact with at least a portion of the shield can 230.

In an embodiment, the second heat transfer member 242 may be disposed to cover the shield can opening 231. For example, at least a portion of the second heat transfer member 242 may be positioned in the opposite direction of the direction in which the printed circuit board 210 is positioned with respect to the shield can opening 231 (e.g., the positive z-axis direction) and disposed to cover the shield can opening 231.

In an embodiment, one surface of the second heat transfer member 242 may refer to the surface of the second heat transfer member 242 that faces the negative z-axis direction. The other surface of the second heat transfer member 242 may refer to the surface of the second heat transfer member 242 that faces the positive z-axis direction.

In an embodiment, the electronic device 200 may include two first heat transfer members 241. When the electronic device 200 includes two first heat transfer members 241, the two first heat transfer members 241 may be disposed with the second heat transfer member 242 interposed therebetween. For example, one of the first heat transfer members 241 may be disposed on one surface of the second heat transfer member 242, and the other first heat transfer member 241 may be disposed on the other surface of the second heat transfer member 242.

In an embodiment, the first frame 250 may include a first disposition space 251 and/or a second disposition space 252. The first disposition space 251 may be a space where the printed circuit board 210, electronic component 220, shield can 230, and/or heat transfer member 240 are disposed. The second disposition space 252 may be a space where the battery 189 (see FIG. 1), which supplies power to the electronic device 200, is disposed.

In an embodiment, at least a portion of the second frame 260 may be disposed inside the first frame 250. The first frame 250 may be disposed to surround at least a portion of the outer periphery of the second frame 260. At least a portion of the second frame 260 may be exposed to the outside of the first frame 250.

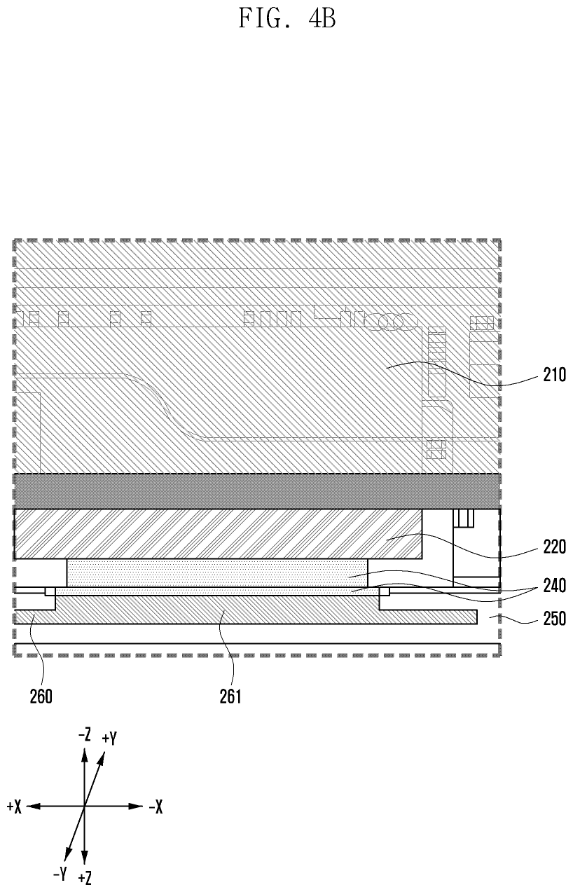

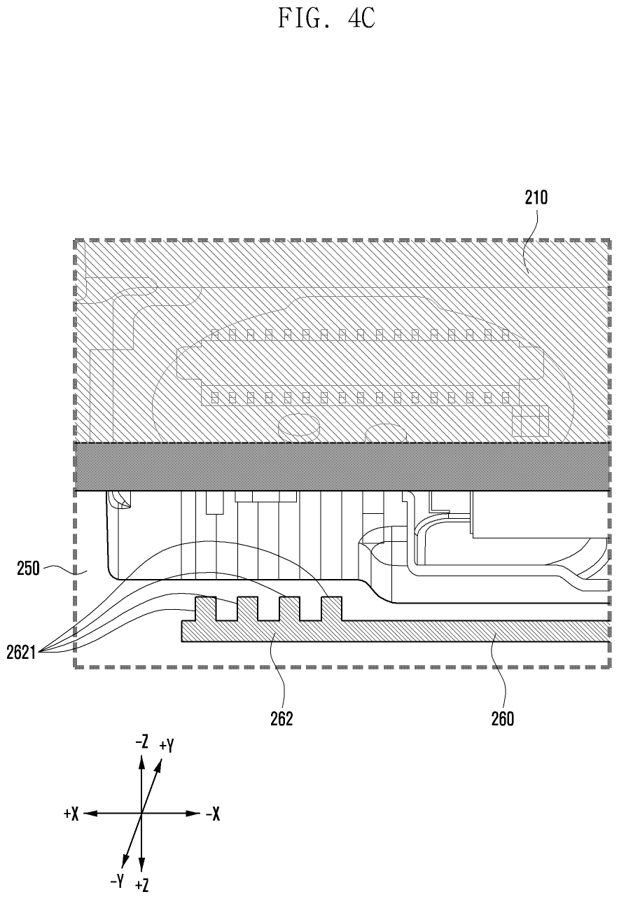

FIG. 4A, FIG. 4B, and FIG. 4C are views illustrating an example electronic device 200 according to various embodiments of the present disclosure.

FIG. 4A is a view of the electronic device 200 according to an embodiment of the present disclosure, taken by cutting the electronic device 200 in the width direction (e.g., the x-axis direction) of the electronic device 200. FIG. 4B is an enlarged view of the A area illustrated in FIG. 4A. FIG. 4C is an enlarged view of the B area illustrated in FIG. 4A.

With reference to FIG. 4A and FIG. 4B, the electronic component 220 may be disposed on one surface of the printed circuit board 210. For example, the electronic component 220 may be disposed on the surface that faces the first frame 250 and second frame 260 in the printed circuit board 210.

In an embodiment, the heat transfer member 240 may be disposed on one surface of the electronic component 220. For example, the heat transfer member 240 may be disposed on the surface that faces the first frame 250 and second frame 260 in the electronic component 220.

The heat transfer member 240 illustrated in FIG. 4A and FIG. 4B may include the first heat transfer member 241 (see FIG. 3) and/or the second heat transfer member 242 (see FIG. 3) illustrated in FIG. 3.

In an embodiment, one surface of the heat transfer member 240 may refer, for example, to the surface of the heat transfer member 240 that faces the negative z-axis direction. The other surface of the heat transfer member 240 may refer, for example, to the surface of the heat transfer member 240 that faces the positive z-axis direction.

With reference to FIG. 4A and FIG. 4B, the heat transfer member 240 may be in contact with the electronic component 220 on one surface of the heat transfer member 240. The heat transfer member 240 may be in contact with the heat transfer part 261 of the second frame 260 on the other surface of the heat transfer member 240.

In an embodiment, at least a portion of the second frame 260 may be exposed to the outside of the first frame 250. With reference to FIG. 4B, the heat transfer part 261 of the second frame 260 may be exposed to the outside of the first frame 250 and be in contact with the heat transfer member 240.

In an embodiment, the heat transfer part 261 may be formed by extending a portion of the second frame 260 in the direction toward the electronic component 220 (e.g., the negative z-axis direction).

In an embodiment, the heat generated by the electronic component 220 may be transferred through the heat transfer member 240 to the heat transfer part 261 of the second frame 260. The heat transfer part 261 may serve to receive the heat generated by the electronic component 220 and transfer the heat to the heat dissipation part 262.

With reference to FIG. 4A, the heat dissipation part 262 of the second frame 260 may be positioned at a distance from the electronic component 220. For example, the heat dissipation part 262 may be positioned at a distance from the electronic component 220 in the width direction of the electronic device 200 (e.g., the x-axis direction). The second frame 260 may be formed by extending in the direction from the electronic component 220 toward the heat dissipation part 262.

In FIG. 4A, the heat dissipation part 262 of the second frame 260 and the electronic component 220 are illustrated as positioned at a distance in the width direction of the electronic device 200 (e.g., the x-axis direction), but, this is illustrative, and the heat dissipation part 262 and the electronic component 220 may also be positioned at a distance in the length direction of the electronic device 200 (e.g., the y-axis direction). In an embodiment, the heat generated by the electronic component 220 may diffuse toward the heat dissipation part 262 along the direction in which the second frame 260 extends.

In an embodiment, the heat dissipation part 262 may serve to dissipate the transferred heat to the outside of the heat dissipation part 262. The heat dissipation part 262 of the second frame 260 may be formed with a larger surface area in contact with the outside compared to other areas of the second frame 260, making it easier to dissipate heat. For example, the heat dissipation part 262 of the second frame 260 may be formed with a larger surface area in contact with the outside compared to other areas of the second frame 260, based on the same unit length (e.g., a length by which the second frame 260 extends by a predetermined amount in the length direction of the electronic device 200).

With reference to FIG. 4A and FIG. 4C, the heat dissipation part 262 may include a first protruding area 2621. The first protruding area 2621 may refer, for example, to an area where a portion of the heat dissipation part 262 protrudes and extends in the height direction of the electronic device 200 (e.g., the z-axis direction).

With reference to FIG. 4A and FIG. 4C, multiple first protruding areas 2621 may be formed in the heat dissipation part 262. Although four first protruding areas 2621 are illustrated as being formed in FIG. 4A and FIG. 4C, this is illustrative, and the number of first protruding areas 2621 is not limited thereto.

In an embodiment, the heat dissipation part 262 of the second frame 260 may include the first protruding area 2621, thereby increasing the surface area in contact with the outside. For example, when the heat dissipation part 262 includes the first protruding area 2621, the surface area of the heat dissipation part 262 in contact with the first frame 250 may increase by the surface area formed by the first protruding area 2621. The surface area of the heat dissipation part 262 in contact with the first frame 250 increases, the heat dissipation part 262 may be easy to dissipate the heat transferred from the electronic component 220.

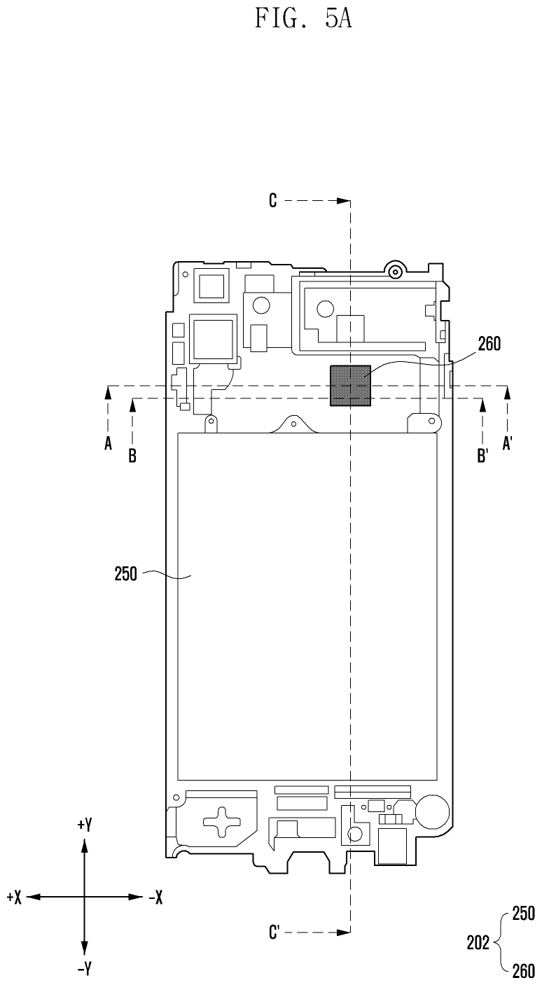

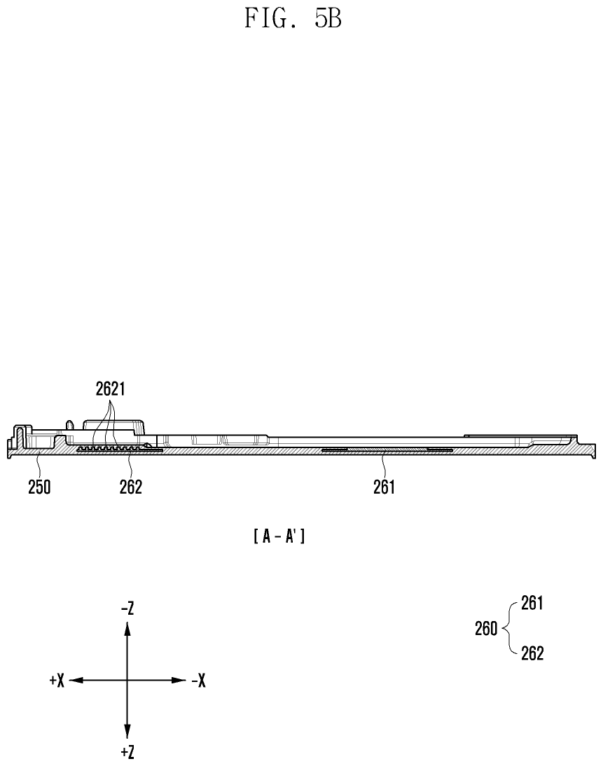

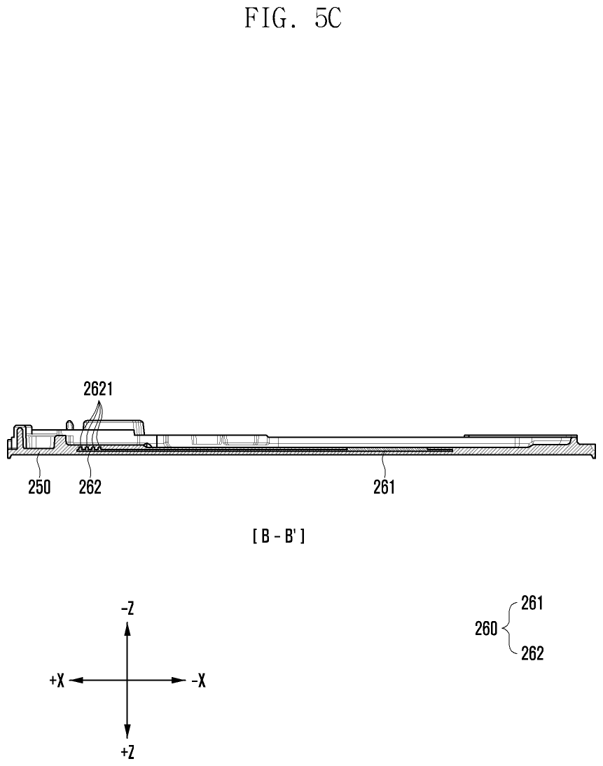

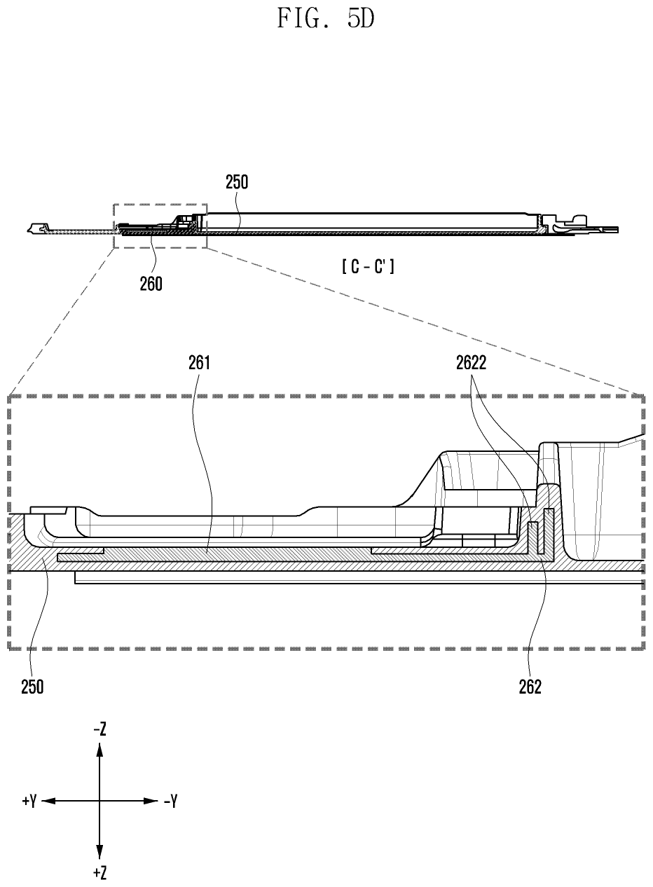

FIG. 5A, FIG. 5B, FIG. 5C, and FIG. 5D are views illustrating an example first frame 250 and an example second frame 260 according to various embodiments of the present disclosure.

FIG. 5A is a view illustrating the first frame 250 and second frame 260 according to an embodiment. FIG. 5B is a cross-sectional view of the first frame 250 and second frame 260 taken along line A-A′ illustrated in FIG. 5A. FIG. 5C is a cross-sectional view of the first frame 250 and second frame 260 taken along the B-B′ line illustrated in FIG. 5A. FIG. 5D is a cross-sectional view of the first frame 250 and second frame 260 taken along the C-C′ line illustrated in FIG. 5A.

In an embodiment, the heat dissipation structure 202 may include the first frame 250 and/or the second frame 260. The first frame 250 may be a frame that forms the outer appearance of the heat dissipation structure 202. The second frame 260 may be a frame disposed inside the first frame 250.

In describing the first frame 250 according to an embodiment of the present disclosure, the width direction, length direction, and height direction of the first frame 250 may be parallel to the width direction, length direction, and height direction of the electronic device 200, respectively. For example, the width direction of the first frame 250 may refer, for example, to the x-axis direction, and the length direction of the first frame 250 may refer, for example, to the y-axis direction. The height direction of the first frame 250 may refer, for example, to the z-axis direction.

With reference to FIG. 5A, FIG. 5B, FIG. 5C, and FIG. 5D, the first frame 250 may extend along the width direction (e.g., the x-axis direction), length direction (e.g., the y-axis direction), and height direction (e.g., the z-axis direction) of the electronic device 200.

With reference to FIG. 5A, FIG. 5B, FIG. 5C, and FIG. 5D, the first frame 250 may be disposed to surround at least a portion of the second frame 260.

With reference to FIG. 5A, FIG. 5B, FIG. 5C, and FIG. 5D, at least a portion of the second frame 260 may be exposed to the outside of the first frame 250. For example, the heat transfer part 261 of the second frame 260 may be exposed to the outside of the first frame 250. The second frame 260 may be in contact with the electronic component 220 (see FIG. 4B) or the heat transfer member 240 (see FIG. 4B) disposed on the electronic component 220 (see FIG. 4B) at the heat transfer part 261.

With reference to FIG. 5B and FIG. 5C, the heat dissipation part 262 may be positioned at a distance from the heat transfer part 261. For example, the heat dissipation part 262 may be disposed at a distance from the heat transfer part 261 by a predetermined length in the width direction of the electronic device 200 (e.g., the x-axis direction).

In an embodiment, the second frame 260 may include multiple heat dissipation parts 262. For example, with reference to FIG. 5B, FIG. 5C, and FIG. 5D, when the second frame 260 includes two heat dissipation parts 262, one of the heat dissipation parts 262 may be positioned at a distance in the width direction of the first frame 250 (e.g., the x-axis direction) based on the heat transfer part 261, while the other heat dissipation part 262 may be positioned at a distance in the length direction of the first frame 250 (e.g., the y-axis direction) based on the heat transfer part 261.

With reference to FIG. 5B, FIG. 5C, and FIG. 5D, each of the heat dissipation parts 262 may include the first protruding area 2621 and/or the second protruding area 2622. The first protruding area 2621 may be positioned at a distance in the width direction of the first frame 250 (e.g., the x-axis direction) based on the heat transfer part 261. The second protruding area 2622 may be positioned at a distance in the length direction of the first frame 250 (e.g., the y-axis direction) based on the heat transfer part 261.

In an embodiment, the first protruding area 2621 and/or the second protruding area 2622 may each be an area where a portion of the heat dissipation part 262 protrudes and extends in the height direction of the first frame 250 (e.g., the z-axis direction). For example, when the heat transfer part 261 forms one surface that is parallel to the width direction (e.g., the x-axis direction) and length direction (e.g., the y-axis direction) of the first frame 250, the first protruding area 2621 and/or the second protruding area 2622 may extend from one surface of the heat transfer part 261 to protrude in the height direction of the first frame 250 (e.g., the z-axis direction).

With reference to FIG. 5B and FIG. 5C, the number of first protruding areas 2621 may be formed differently depending on the position of the heat dissipation part 262. For example, the number of first protruding areas 2621 formed at the A-A′ cross-sectional position of the second frame 260 may be greater than the number of first protruding areas 2621 formed at the B-B′ cross-sectional position.

In an embodiment, the length by which the first protruding area 2621 extends and the length by which the second protruding area 2622 extends may be formed differently from each other. For example, the length by which the second protruding area 2622 protrudes and extends in the height direction of the first frame 250 (e.g., the z-axis direction), may be longer than the length by which the first protruding area 2621 protrudes and extends.

In an embodiment, the extended length of the first protruding area 2621 and/or the second protruding area 2622 may vary based on the shape of the first frame 250 where the heat dissipation part 262 is disposed. For example, the heat dissipation part 262 disposed in an area where the first frame 250 is formed to be longer in the height direction (e.g., the z-axis direction) may be formed with a longer extension of the first protruding area 2621 and/or the second protruding area 2622 compared to the heat dissipation part 262 disposed in another area of the first frame 250.

In an embodiment, multiple first protruding areas 2621 and/or multiple second protruding areas 2622 may be formed in a portion of the heat dissipation part 262. With reference to FIG. 5B, FIG. 5C, and FIG. 5D, although the number of first protruding areas 2621 is illustrated as being greater than the number of second protruding areas 2622, this is illustrative, and the number of first protruding areas 2621 and second protruding areas 2622 is not limited thereto.

In an embodiment, the first frame 250 may include a material with a lower melting point compared to the second frame 260. For example, the second metal of the second frame 260 may include copper or copper alloys, while the first metal of the first frame 250 may include aluminum, magnesium, or zinc, which have a lower melting point compared to the second metal.

In an embodiment, the first frame 250 may include a material with a lower thermal conductivity compared to the second frame 260.

In an embodiment, the first frame 250 may be manufactured using the die casting method. For example, after the second frame 260 is manufactured, the first frame 250 may be manufactured using the die casting method on the outside of the second frame 260. Since the first metal included in the first frame 250 may have a lower melting point compared to the second metal included in the second frame 260, the first frame 250 may be formed on the outside of the second frame 260 through the die casting method while the second frame 260 has been disposed.

In an embodiment, the first metal of the first frame 250 may include a metal to which the die casting method is applicable.

In an embodiment, the first frame 250 may be manufactured using the metal injection molding (MIM) method.

In an embodiment, the first metal of the first frame 250 may include a metal to which the metal injection molding (MIM) method is applicable.

In an embodiment, after the first frame 250 is formed on the outside of the second frame 260, additional processes may be performed on both the first frame 250 and the second frame 260. For example, a process for forming a film on the surface of the first frame 250 (e.g., anodizing, chromating), a process for refining the outer surfaces of the first frame 250 and the second frame 260 (e.g., sanding), and/or a process for surface protection and aesthetic formation of the first frame 250 and the second frame 260 (e.g., painting) may be performed.

Although FIG. 5A, FIG. 5B, and FIG. 5C illustrate only the heat transfer part 261 of the second frame 260 being exposed to the outside of the first frame 250, this is illustrative, and the portion of the second frame 260 exposed to the outside of the first frame 250 is not limited thereto. For example, the heat dissipation part 262 of the second frame 260 may not only be positioned inside the first frame 250 but may also be exposed to the outside through one surface of the first frame 250. The heat dissipation part 262 may be exposed to the outside of the first frame 250 through a surface of the first frame 250 that faces the negative z-axis direction or a surface that faces the positive z-axis direction.

In an embodiment, when the heat dissipation part 262 is exposed to the outside of the first frame 250, a cooling member (not illustrated) may be disposed on the heat dissipation part 262 exposed to the outside. The cooling member (not illustrated) may serve to cool the heat of the heat dissipation part 262.

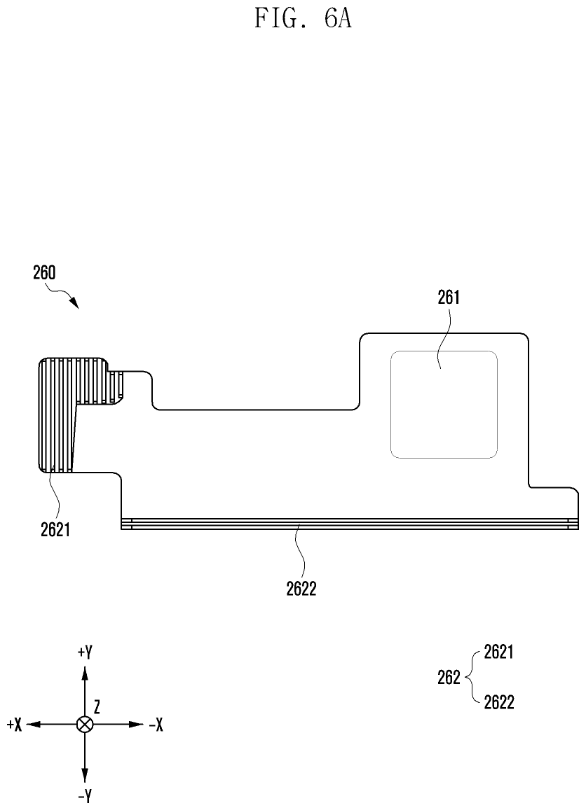

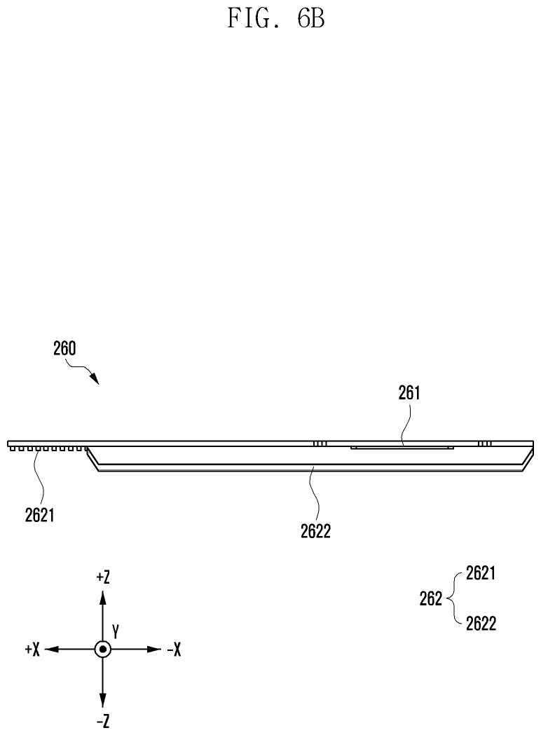

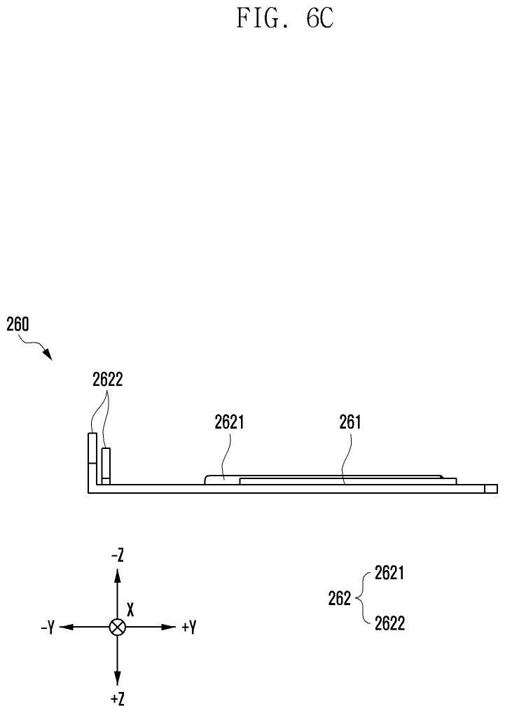

FIG. 6A, FIG. 6B, and FIG. 6C are views illustrating an example second frame 260 according to various embodiments of the present disclosure.

FIG. 6A is a view of the second frame 260 according to an embodiment of the present disclosure, viewed in the positive z-axis direction. FIG. 6B is a view of the second frame 260 according to an embodiment of the present disclosure, viewed in the negative y-axis direction. FIG. 6C is a view of the second frame 260 according to an embodiment of the present disclosure, viewed in the positive x-axis direction.

In describing the second frame 260 according to an embodiment of the present disclosure, the width direction of the second frame 260 may refer, for example, to the x-axis direction, and the length direction may refer, for example, to the y-axis direction. The height direction of the second frame 260 may refer, for example, to the z-axis direction.

In an embodiment, the second frame 260 may include a plate shape. For example, the second frame 260 may have a thickness in the height direction (e.g., the z-axis direction) and be formed to extend in the width direction (e.g., the x-axis direction) and length direction (e.g., the y-axis direction).

With reference to FIG. 6A, FIG. 6B, and FIG. 6C, the second frame 260 according to an embodiment of the present disclosure may include the heat transfer part 261 and/or the heat dissipation part 262.

With reference to FIG. 6A, FIG. 6B, and FIG. 6C, a partial area of the second frame 260 may be formed thicker compared to other areas. For example, the heat transfer part 261 of the second frame 260 may be formed thicker compared to other areas.

In an embodiment, the heat dissipation part 262 may include the first protruding area 2621 and/or the second protruding area 2622. The first protruding area 2621 and the second protruding area 2622 may refer to areas where a portion of the heat dissipation part 262 protrudes and extends in the height direction (e.g., the z-axis direction) of the second frame 260.

With reference to FIG. 6A, FIG. 6B, and FIG. 6C, the first protruding area 2621 may extend along a direction that is substantially parallel to the length direction (e.g., the y-axis direction) of the second frame 260. The second protruding area 2622 may extend along a direction that is substantially parallel to the width direction (e.g., the x-axis direction) of the second frame 260.

In an embodiment, the heat transfer part 261 may be positioned at a distance from the heat dissipation part 262 by a predetermined length. For example, the first protruding area 2621 of the heat transfer part 261 may be positioned at a distance from the heat transfer part 261 in the width direction (e.g., the x-axis direction) of the second frame 260. The second protruding area 2622 of the heat transfer part 261 may be positioned at a distance from the heat transfer part 261 in the length direction (e.g., the y-axis direction) of the second frame 260.

With reference to FIG. 6A, the second frame 260 may include a shape that is bent and extends in at least a portion. For example, the second frame 260 may extend in the width direction (e.g., the x-axis direction) of the second frame 260 in a direction from the heat transfer part 261 toward the first protruding area 2621 of the heat dissipation part 262, while being bent in the length direction (e.g., the y-axis direction) of the second frame 260 in at least a portion. The shape in which the second frame 260 is bent and extends may vary based on the shape of the first frame 250 and the shape of other components of the electronic device 200 (e.g., printed circuit board 210).

With reference to FIG. 6B and FIG. 6C, the length of extension of the first protruding area 2621 and the second protruding area 2622 may be formed differently from each other. For example, the length by which the second protruding area 2622 protrudes and extends in the height direction of the first frame 250 (e.g., the z-axis direction), may be longer than the length by which the first protruding area 2621 protrudes and extends. The lengths of extension of the first protruding area 2621 and the second protruding area 2622 may vary based on the shape of the first frame 250 (see FIG. 5B).

In an embodiment, the cross-sections of the first protruding area 2621 and the second protruding area 2622 may refer to the cross-section formed substantially perpendicular to the z-axis direction in the first protruding area 2621 and the second protruding area 2622.

In FIG. 6A, FIG. 6B, and FIG. 6C, the cross-sections of the first protruding area 2621 and the second protruding area 2622 are illustrated as rectangular shapes, but, this is illustrative, and the cross-sections of the first protruding area 2621 and the second protruding area 2622 are not limited thereto. For example, the cross-section of the first protruding area 2621 and/or the second protruding area 2622 may include a circular shape or a polygonal shape that is not rectangular.

In FIG. 6A, FIG. 6B, and FIG. 6C, the first protruding area 2621 and the second protruding area 2622 are illustrated as protruding and extending in the negative z-axis direction from one surface of the second frame 260, but, this is illustrative, and the direction in which each protruding area 2621 or 2622 extends is not limited thereto. For example, the first protruding area 2621 and the second protruding area 2622 may protrude and extend in the positive z-axis direction from the other surface of the second frame 260. Alternatively, the first protruding area 2621 and the second protruding area 2622 may protrude and extend in the negative z-axis direction from one surface of the second frame 260, and in the positive z-axis direction from the other surface of the second frame 260.

In an embodiment, the second frame 260 may include a metal with a higher thermal conductivity compared to the metal included in the first frame 250. For example, the second frame 260 may include copper and/or copper alloys.

In an embodiment, the second frame 260 may further include nanomaterials for improving thermal conductivity. For example, the second frame 260 may include graphite and/or graphene nanopowder based on copper and/or copper alloys to enhance thermal conductivity.

An electronic device 200 according to an example embodiment of the present disclosure may include a heat generating element 201 that includes an electronic component 220 in which heat is generated during the operation of the electronic device 200, and a heat dissipation structure 202 that supports the heat generating element 201.

In an example embodiment, the heat dissipation structure 202 may include a first frame 250 that includes a first metal, and a second frame 260 that includes a second metal, where at least a portion of the second frame 260 is disposed inside the first frame 250 and at least a portion of the second frame 260 is exposed to the outside through one surface of the first frame 250.

In an example embodiment, the second frame 260 may include a heat transfer part 261 that is in contact with the heat generating element 201 and a heat dissipation part 262 that is disposed at a distance from the heat generating element 201.

In an example embodiment, the heat transfer part 261 may serve to receive the heat generated by the electronic component 220 and transfer the heat to the heat dissipation part 262.

In an example embodiment, the second frame 260 may extend from the heat transfer part 261 to the heat dissipation part 262.

In an example embodiment, the heat generating element 201 may include a heat transfer member 240 that is in contact with the electronic component 220 on one surface and in contact with the heat dissipation structure 202 on the other surface, thereby transferring the heat generated by the electronic component 220 to the heat dissipation structure 202.

In an example embodiment, the heat generating element 201 may include a printed circuit board 210 on which the electronic component 220 is disposed, and a shield can 230 that includes a shield can opening 231 disposed at a position overlapping the electronic component 220, and is disposed to surround an outer periphery of the electronic component 220.

In an example embodiment, the heat generating element 201 may include the heat transfer member 240 that transfers the heat generated by the electronic component 220 to the heat dissipation structure 202.

In an example embodiment, the heat transfer member 240 may include a first heat transfer member 241 that is in contact with the electronic component 220 at a position overlapping the shield can opening 231, and a second heat transfer member 242 that is in contact with the shield can 230 and the first heat transfer member 241 on one surface, and in contact with the heat dissipation structure 202 on the other surface.

In an example embodiment, the heat dissipation part 262 of the second frame 260 may be formed with a larger surface area in contact with the outside, compared to other areas of the second frame 260, based on the same unit length.

In an example embodiment, the surface area of the heat dissipation part 262 in contact with the outside increases, the heat dissipation part 262 may be easy to dissipate the heat transferred from the electronic component 220.

In an example embodiment, the heat dissipation part 262 may include multiple protruding areas 2621 and 2622 that protrude and extend in the height direction of the electronic device 200 from one surface of the heat dissipation part 262.

In an example embodiment, the heat dissipation part 262 may include the protruding areas 2621 and 2622, thereby increasing the surface area in contact with the outside. In an example embodiment, multiple protruding areas 2621 and 2622 may be disposed to be spaced apart from each other.

In an example embodiment, the protruding areas 2621 and 2622 may include a cross-section of a rectangular shape.

In an example embodiment, the protruding areas 2621 and 2622 of the heat dissipation part 262 may include a first protruding area 2621 that is positioned at a distance from the heat transfer part 261 in the width direction of the electronic device 200, and a second protruding area 2622 that is positioned at a distance from the heat transfer part 261 in the length direction of the electronic device 200.

In an example embodiment, a length by which the first protruding area 2621 protrudes and extends in the height direction of the electronic device 200 and a length by which the second protruding area 2622 protrudes and extends in the height direction of the electronic device 200 may be different from each other.

In an example embodiment, the first protruding area 2621 may extend along the length direction of the electronic device 200, and the second protruding area 2622 may extend along the width direction of the electronic device 200.

In an example embodiment, the thermal conductivity of the first metal may be lower than the thermal conductivity of the second metal.

In an example embodiment, the melting point of the first metal may be lower than the melting point of the second metal.

In an example embodiment, the first frame 250 may be manufactured using a die casting method on the outer periphery of the second frame 260.

In an example embodiment, since the first metal included in the first frame 250 may have a lower melting point compared to the second metal included in the second frame 260, the first frame 250 may be formed on the outside of the second frame 260 through the die casting method while the second frame 260 has been disposed.

In an example embodiment, the first frame 250 may be manufactured using a metal injection molding method.

In an example embodiment, the first metal may include aluminum, magnesium, and/or zinc, and the second metal may include copper and/or copper alloys.

In an example embodiment, the second frame 260 may include graphene nanopowder to improve thermal conductivity.

In an example embodiment, the heat dissipation structure 202 may include a first frame 250 that includes a first metal, and a second frame 260 that includes a second metal, where at least a portion of the second frame 260 is disposed inside the first frame 250 and at least a portion of the second frame 260 is exposed to the outside through one surface of the first frame 250.

In an example embodiment, the second frame 260 may include a heat transfer part 261 that receives heat generated by an external heat source and a heat dissipation part 262 that is disposed at a distance from the external heat source.

An electronic device according to an embodiment of the present disclosure may be one of various types of electronic devices. The electronic device may include, for example, a portable communication device (e.g., a smartphone), a computer device, a portable multimedia device, a portable medical device, a camera, a wearable device, a home appliance, or the like. The electronic device according to the embodiment of the present disclosure is not limited to the above-mentioned devices.

An embodiment of the present disclosure and the terms used in the embodiment are not intended to limit the technical features disclosed in the present disclosure to the particular embodiments and should be understood as including various alterations, equivalents, or alternatives of the corresponding embodiments. In connection with the description of the drawings, the similar reference numerals may be used for the similar or relevant constituent elements. The singular form of a noun corresponding to an item may include one or plurality of the items, unless the relevant context clearly indicates otherwise. As used herein, each of such phrases as “A or B,” “at least one of A and B,” “at least one of A or B,” “A, B, or C,” “at least one of A, B, and C,” “at least one of A, B, or C,” and “at least one of A, B, and/or C” may include any one of, or all possible combinations of the items enumerated together in a corresponding one of the phrases. Such terms as “1st” and “2nd,” or “first” and “second” may be used to simply distinguish a corresponding constituent element from another, and do not limit the constituent elements in other aspect (e.g., importance or order). When a constituent element (e.g., a first constituent element) is referred to, with or without the term “operatively” or “communicatively,” as “coupled with,” “coupled to,” “connected with,” or “connected to” another constituent element (e.g., a second constituent element), the constituent element may be coupled with the other constituent element directly (e.g., wiredly), wirelessly, or via a third constituent element.

The term “module” used in an embodiment of the present disclosure may include a unit implemented in hardware, software, or firmware, or any combination thereof, and may interchangeably be used with other terms, for example, “logic,” “logic block,” “component,” or “circuitry”. The module may be a single integral component, or a minimum unit or part thereof, adapted to perform one or more functions. For example, according to an embodiment, the module may be implemented in a form of an application-specific integrated circuit (ASIC).

According to an embodiment, each constituent element (e.g., module or program), among the above-mentioned constituent elements, may include a single object or a plurality of objects, and some of the plurality of objects may be disposed separately in different constituent elements. According to various embodiments, one or more constituent elements, among the above-mentioned constituent elements, or operations may be omitted, or one or more other constituent elements or operations may be added. Alternatively or additionally, a plurality of constituent elements (e.g., modules or programs) may be integrated into a single constituent element. In this case, the integrated constituent element may perform one or more functions of each of the plurality of constituent elements in the same or similar manner as they are performed by a corresponding one of the plurality of constituent elements before the integration.

Various embodiments of the disclosure have been described above. The above description of the disclosure has been given by way of example, and embodiments of the disclosure are not limited to the embodiments disclosed herein. Those skilled in the art will appreciate that the disclosure may be easily modified into other specific forms without departing from the technical idea or essential features of the disclosure. The scope of the disclosure is defined by the appended claims, rather than the above detailed description, and the scope of the disclosure should be construed to include all changes or modifications derived from the meaning and scope of the claims and equivalents thereof.

What is claimed is:

1. An electronic device, comprising:
an electronic component in which heat is generated during an operation of the electronic device; and
a heat dissipation structure configured to support the electronic component,
wherein the heat dissipation structure includes:
a first frame including a first metal; and
a second frame, at least a portion of which is disposed inside the first frame and at least a portion of which is exposed to the outside through one surface of the first frame, and including a second metal,
wherein the second frame includes a heat transfer part in contact with the electronic component, and a heat dissipation part disposed at a distance from the electronic component, the second frame extending from the heat transfer part to the heat dissipation structure.

2. The electronic device of claim 1, wherein the electronic device further includes a heat transfer member in contact with the electronic component on one surface and in contact with the heat dissipation structure on the other surface to transfer heat generated by the electronic component to the heat dissipation structure.

3. The electronic device of claim 1, wherein the electronic device further includes:
a printed circuit board on which the electronic component is disposed; and
a shield can including a shield can opening disposed in a position corresponding to the electronic component, and disposed to surround an outer periphery of the electronic component.

4. The electronic device of claim 3, wherein the electronic device further includes:
a heat transfer member configured to transfer heat generated by the electronic component to the heat dissipation structure,
wherein the heat transfer member includes:
a first heat transfer member in contact with the electronic component in a position corresponding to the shield can opening; and
a second heat transfer member in contact with the shield can and the first heat transfer member on one surface and in contact with the heat dissipation structure on another other surface.

5. The electronic device of claim 1, wherein the heat dissipation part of the second frame is formed with a larger surface area in contact with the outside, compared to other areas of the second frame, based on a same unit length.

6. The electronic device of claim 1, wherein the heat dissipation part includes multiple protruding areas protruding and extending from one surface of the heat dissipation part in a height direction of the electronic device, the multiple protruding areas being disposed spaced apart from each other.

7. The electronic device of claim 6, wherein one or more of the multiple protruding areas includes a cross-section of a rectangular shape.

8. The electronic device of claim 6, wherein the multiple protruding areas of the heat dissipation part include:
a first protruding area positioned at a distance from the heat transfer part in a width direction of the electronic device; and
a second protruding area positioned at a distance from the heat transfer part in a length direction of the electronic device.

9. The electronic device of claim 8, wherein a length by which the first protruding area protrudes and extends in the height direction of the electronic device and a length by which the second protruding area protrudes and extends in the height direction of the electronic device differ from each other.

10. The electronic device of claim 8, wherein the first protruding area extends along the length direction of the electronic device, and the second protruding area extends along the width direction of the electronic device.

11. The electronic device of claim 1, wherein thermal conductivity of the first metal is lower than thermal conductivity of the second metal, and a melting point of the first metal is lower than a melting point of the second metal.

12. The electronic device of claim 1, wherein the first frame is die cast on an outer periphery of the second frame.

13. The electronic device of claim 1, wherein the first frame is metal injection molded.

14. The electronic device of claim 1 1, wherein the first metal includes aluminum, magnesium, and/or zinc, and the second metal includes copper and/or copper alloys.

15. The electronic device of claim 1, wherein the second frame includes graphene nanopowder.

16. A heat dissipation structure, comprising:
a first frame including a first metal; and
a second frame, at least a portion of which is disposed inside the first frame and at least a portion of which is exposed to the outside through one surface of the first frame, and including a second metal,
wherein the second frame includes a heat transfer part receiving heat generated by an external heat source, and a heat dissipation part disposed at a distance from the external heat source, the second frame extending from the heat transfer part to the heat dissipation structure

17. The heat dissipation structure of claim 16, wherein the heat dissipation part of the second frame is formed with a larger surface area in contact with the outside, compared to other areas of the second frame, based on a same unit length.

18. The heat dissipation structure of claim 16, wherein the heat dissipation part includes multiple protruding areas protruding and extending from one surface of the heat dissipation part in a height direction of the second frame, the multiple protruding areas being disposed spaced apart from each other.

19. The heat dissipation structure of claim 16, wherein the first frame is die cast on an outer periphery of the second frame.

20. The heat dissipation structure of claims 16, wherein the first metal includes aluminum, magnesium, and/or zinc, and the second metal includes copper and/or copper alloys.
